(19) United States
(12) Patent Application Publication
(10) Pub. No.: US 2014/0070831 A1
(43) Pub. Date: Mar. 13, 2014

(54) SYSTEM AND METHOD OF PROTECTING PROBES BY USING AN INTELLIGENT CURRENT SENSING SWITCH

(71) Applicant: Advantest Corporation, (US)

(72) Inventors: Eric Barr KUSHNICK, San Jose, CA (US); David H. ARMSTRONG, Lafayette, CO (US); Karl PEDERSEN, San Jose, CA (US)

(73) Assignee: ADVANTEST CORPORATION, Tokyo (JP)

(21) Appl. No.: 13/781,607

(22) Filed: Feb. 28, 2013

Related U.S. Application Data
(60) Provisional application No. 61/693,692, filed on Aug. 27, 2012.

(51) Int. Cl. G01R 1/36; H01H 71/74

(52) U.S. Cl. CPC G01R 1/36; H01H 71/74
USPC 324/754.07

(57) ABSTRACT

An apparatus and method for protecting probes used in automated testing is disclosed. The apparatus comprises a probe operable to provide power to a device under test (DUT) from a device power source (DPS), wherein the probe is coupled to a contact point on the DUT and a probe protector circuit connected to the probe in series between the DPS and the DUT. The probe protector circuit further comprises a current sense module operable to monitor a flow of current from the DPS to the DUT to determine if the current flow is below a predetermined threshold current level and a switch for controlling the connection from the DPS to the DUT. The switch is coupled to the current sense module and is operable to be used in conjunction with the current sense module to limit the current flow if it exceeds the predetermined threshold current level.

### CROSS-REFERENCE TO RELATED APPLICATIONS

This application claims priority from U.S. Provisional Application No. 61/693,692, Attorney Docket ATST-U0093.A, filed Aug. 27, 2012, assigned to the assignee of the present invention and the entire disclosure of which is incorporated herein by reference.

### FIELD OF THE INVENTION

Embodiments according to the present invention generally relate to automated test equipment and more specifically to current monitoring techniques used in automated test equipment.

### BACKGROUND OF THE INVENTION

Automated test equipment (ATE) can be any testing assembly that performs a test on a device under test (DUT), which can, among other things, be an integrated circuit (IC) or chip on a semiconductor wafer, or a device such as a solid-state drive. ATE assemblies may be used to execute automated tests that quickly perform measurements and generate test results that can then be analyzed. An ATE assembly may be anything from a computer system coupled to a meter, to a complicated automated test assembly that may include a custom, dedicated computer control system and many different test instruments that are capable of automatically testing electronics parts and/or semiconductor wafer testing, such as system-on-chip (SOC) testing or integrated circuit testing. ATE systems both reduce the amount of time spent on testing devices to ensure that the device functions as designed and serve as a diagnostic tool to determine the presence of faulty components within a given device before it reaches the consumer.

In a typical automated test, a probe card is used to probe the semiconductor chips on a wafer. A probe card usually has several probes on it that are placed against the bonding pads on a chip to perform a functional test. In a typical test, probes are used to electrically stimulate the circuit on the chip and to take measurements to determine whether the circuit is functioning properly. Some of the probes on the probe card carry power to the chip from a device power source (DPS). Depending on the amount of power the chip requires, many or all of the probes will be drawing power from the same DPS. In certain instances, if a DUT is defective and is shorted, or if too much current is drawn from the DPS for any other reason, the probe tips used to transmit power from the DPS to the DUT may burn and recede. In such instances, the probe tips will either melt or over time accumulate non-conductive residues and deposits on them that will prevent them from functioning properly. Probe cards are extremely expensive and replacing probe tips on the probe cards if they get damaged is a time consuming and cost prohibitive process. Further, IC chips connected to the damaged probe tips may erroneously be flagged as non-compliant if tests are run without realizing that the probe tips are damaged.

In conventional systems, it has been possible to employ at least two techniques to prevent the burning of probes used to supply power from a DPS. The first typical technique that has been employed to prevent probe tip damage starts with making sure the DPS is at 0 Volts (V) and that it has fully discharged any capacitance on the probe card before contacting the DUT. This may involve waiting a certain time and making a measurement of the residual voltage at the probe card to insure that it has reached 0V. This technique, however, is time-consuming.

The second typical technique involves setting the DPS to a low voltage and a low current clamp setting after the probe tip has made contact with the DUT. Then the effective current measurement of the current clamp is determined to see if the DUT is shorted. If the measurements indicate that the DUT is shorted, the user will be alerted not to power the DUT up. This technique is also time-consuming because the user needs to power the DUT up at a low voltage and current clamp setting first to take measurements in order to determine whether the system is ready for use.

In certain instances, the second technique discussed above can also be ineffective. For example, in some cases there are several independent groups of circuits on a DUT that operate at the same voltage but have independent power connections that are not mutually connected. Due to tester configuration, it may be advantageous to connect the probes for all these voltage rails to a common, high current power supply. The second technique may be less practical in these configurations because the extra current drawn at low voltages by a short on one voltage rail may be masked by the normal currents drawn on the other voltage rails. When full power is applied, the probes connected to the shorted voltage rail can be burned. Further, if there are many probes connected in parallel, it is difficult to identify the shorted voltage rail. Also, if full power is applied under these circumstances, it can result in a cascade effect wherein after a probe connected to the shorted rail burns, the increased current through the remainder of the probes connected to that voltage rail can cause them to burn as well.

Thus, conventional methods of preempting probe damage from excessive current are time-consuming because there is no intelligence built into the systems for switching off the current passing through a probe tip if it exceeds an acceptable threshold. Further, they are also ineffective in certain tester configurations that make it difficult to identify the shorted voltage rails.

### BRIEF SUMMARY OF THE INVENTION

Accordingly, a need exists for a tester system and/or method that can address the problems with the systems described above. What is needed is a faster and more efficient mechanism to protect probe tips on a probe card from excessive current draw and to make it easier to identify shorted connections under all tester configurations.

Using the beneficial aspects of the systems described, without their respective limitations, embodiments of the present invention provide novel solutions to the challenges inherent in protecting probes used to supply power from a DPS from over-current during device testing.

In one embodiment, a method of protecting probes used in automated testing is disclosed, which comprises coupling a probe to a contact point on a device under test (DUT), wherein the probe is operable to provide power to the DUT from a device power source (DPS). It further comprises connecting a probe protector circuit to the probe in series between the DPS and the DUT to monitor a flow of current from the DPS to the DUT. Also, it comprises monitoring the flow of current to determine if the current flow is below a predetermined threshold current. Finally the method comprises limiting the current flow if the current flow exceeds the predetermined threshold current.

In one embodiment, an apparatus for protecting probes used in automated testing is disclosed. The apparatus comprises a probe operable to provide power to a device under test (DUT) from a device power source (DPS), wherein the probe is coupled to a contact point on the DUT and a probe protector circuit connected to the probe in series between the DPS and the DUT. The probe protector circuit further comprises a current sense module operable to monitor a flow of current from the DPS to the DUT to determine if the current flow is below a predetermined threshold current level and a switch for controlling the connection from the DPS to the DUT. The switch is coupled to the current sense module and is operable to be used in conjunction with the current sense module to limit the current flow if it exceeds the predetermined threshold current level.

In another embodiment, a tester system is disclosed. The tester system comprises a test head comprising at least one device power source (DPS) and a probe card comprising a plurality of power probes, wherein the power probes are connected to and derive power from the DPS. It further comprises a prober for positioning at least one wafer, wherein the wafer comprises a plurality of devices under test (DUTs) to be tested. The probe card is lowered onto the wafer so that each of the plurality of power probes can connect and provide power to an associated DUT on the wafer. Each of the plurality of power probes comprises a probe protector circuit connected to the probe in series between the DPS and the associated DUT. The probe protector circuit comprises a current sense module operable to monitor a flow of current from the DPS to the associated DUT to determine if the current flow is below a predetermined threshold current level. The protector circuit also comprises a switch for controlling the connection from the DPS to the associated DUT, wherein the switch is coupled to the current sense module and further wherein the switch is operable to be used in conjunction with the current sense module to limit the current flow if it exceeds the predetermined threshold current level.

The following detailed description together with the accompanying drawings will provide a better understanding of the nature and advantages of the present invention.

### BRIEF DESCRIPTION OF THE DRAWINGS

Embodiments of the present invention are illustrated by way of example, and not by way of limitation, in the figures of the accompanying drawings and in which like reference numerals refer to similar elements.

FIG. 1 is a block diagram illustrating the interconnections between the probe protector circuit(s), the DPS and the DUT in accordance with an embodiment of the present invention.

FIG. 2 is a top level diagram of an exemplary system to test semiconductor chips in accordance with an embodiment of the present invention.

FIG. 3 is an exemplary pin diagram for a typical probe protector circuit according to an embodiment of the present invention.

FIG. 4 is an exemplary schematic of the probe protector circuit according to an embodiment of the present invention.

FIG. 5 is a flowchart of an exemplary method of protecting probes by using an intelligent current sensing switch to limit or turn off the current when a defective DUT is encountered in accordance with an embodiment of the present invention

FIG. 6 is a waveform diagram illustrating normal operation of the testing apparatus in accordance with one embodiment of the present invention.

FIG. 7 is a waveform diagram illustrating how a short on one of the DUTs is handled by the probe protector circuit in accordance with one embodiment of the present invention.

FIG. 8 is a magnified view of event T415 from FIG. 7 illustrating the behavior of current I-dut when a shorted DUT is encountered in accordance with one embodiment of the present invention.

FIG. 9 is a waveform diagram illustrating normal operation of the testing apparatus with the SafeStart signal connected to the DPS in accordance with one embodiment of the present invention.

FIG. 10 is a magnified view of event T770 from FIG. 9 illustrating the behavior of signal L̅i̅m̅i̅t̅/̅O̅p̅e̅n̅ when the SafeStart signal is connected to the DPS in accordance with one embodiment of the present invention.

FIG. 11 is a waveform diagram illustrating how a short on one of the DUTs is handled by the probe protector circuit when the SafeStart signal is connected to the DPS in accordance with one embodiment of the present invention.

FIG. 12 is a magnified view of timeframe T915 from FIG. 11 illustrating the behavior of current I-dut when a shorted DUT is encountered with the SafeStart signal connected to the DPS in accordance with one embodiment of the present invention.

In the figures, elements having the same designation have the same or similar function.

### DETAILED DESCRIPTION OF THE INVENTION

Reference will now be made in detail to the various embodiments of the present disclosure, examples of which are illustrated in the accompanying drawings. While described in conjunction with these embodiments, it will be understood that they are not intended to limit the disclosure to these embodiments. On the contrary, the disclosure is intended to cover alternatives, modifications and equivalents, which may be included within the spirit and scope of the disclosure as defined by the appended claims. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

Some portions of the detailed descriptions that follow are presented in terms of procedures, logic blocks, processing, and other symbolic representations of operations on data bits within a computer memory. These descriptions and representations are the means used by those skilled in the data processing arts to most effectively convey the substance of their work to others skilled in the art. In the present application, a procedure, logic block, process, or the like, is conceived to be a self-consistent sequence of steps or instructions leading to a desired result. The steps are those utilizing physical manipulations of physical quantities. Usually, although not necessarily, these quantities take the form of electrical or magnetic signals capable of being stored, transferred, combined, compared, and otherwise manipulated in a computer system. It has proven convenient at times, principally for reasons of common usage, to refer to these signals as transactions, bits, values, elements, symbols, characters, samples, pixels, or the like.

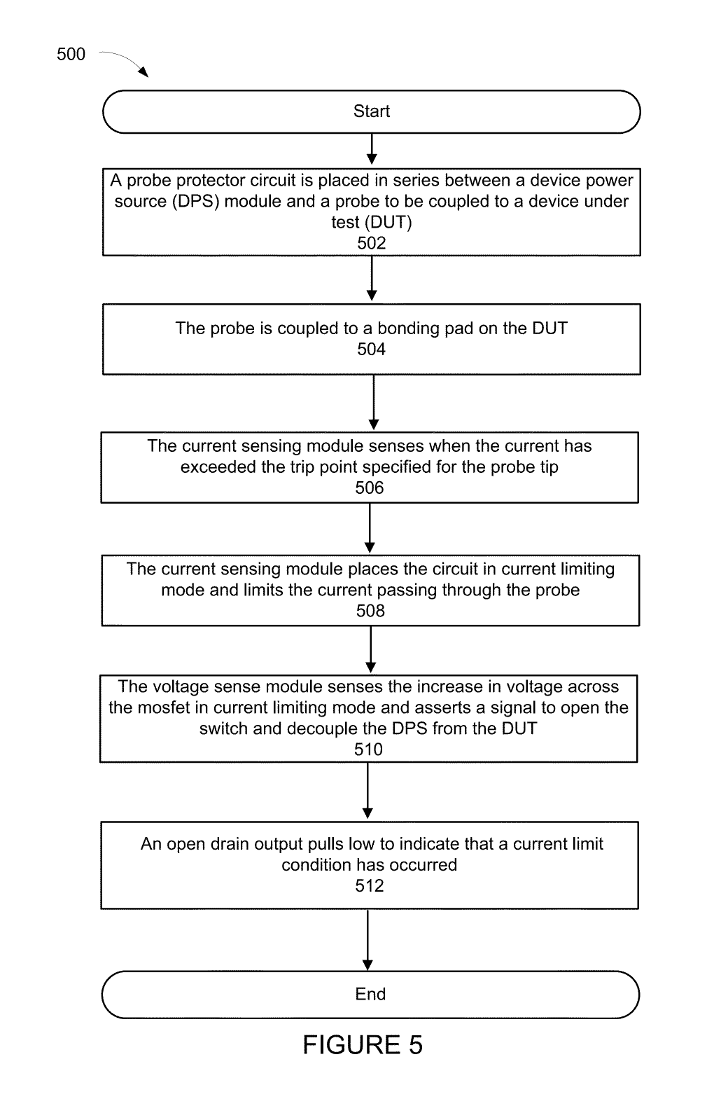

It should be borne in mind, however, that all of these and similar terms are to be associated with the appropriate physical quantities and are merely convenient labels applied to these quantities. Unless specifically stated otherwise as apparent from the following discussions, it is appreciated that throughout the present disclosure, discussions utilizing terms such as “allocating,” “associating,” “moving,” “copying,” “setting,” “accessing,” “erasing,” “freeing,” “controlling,” “adding,” “recording,” “determining,” “identifying,” “caching,” “maintaining,” “incrementing,” “comparing,” “removing,” “reading,” “writing,” or the like, refer to actions and processes (e.g., flowchart 500 of FIG. 5) of a computer system or similar electronic computing device or processor. The computer system or similar electronic computing device manipulates and transforms data represented as physical (electronic) quantities within the computer system memories, registers or other such information storage, transmission or display devices.

The description below provides a discussion of computers and other devices that may include one or more modules. As used herein, the term “module” or “block” may be understood to refer to software, firmware, hardware, and/or various combinations thereof. It is noted that the blocks and modules are exemplary. The blocks or modules may be combined, integrated, separated, and/or duplicated to support various applications. Also, a function described herein as being performed at a particular module or block may be performed at one or more other modules or blocks and/or by one or more other devices instead of or in addition to the function performed at the described particular module or block. Further, the modules or blocks may be implemented across multiple devices and/or other components local or remote to one another. Additionally, the modules or blocks may be moved from one device and added to another device, and/or may be included in both devices. Any software implementations of the present invention may be tangibly embodied in one or more storage media, such as, for example, a memory device, a floppy disk, a compact disk (CD), a digital versatile disk (DVD), or other devices that may store computer code.

The terminology used herein is for the purpose of describing particular embodiments only and is not intended to limit the scope of the present invention. As used throughout this disclosure, the singular forms “a,” “an,” and “the” include plural reference unless the context clearly dictates otherwise. Thus, for example, a reference to “a module” includes a plurality of such modules, as well as a single module, and equivalents thereof known to those skilled in the art.

Embodiments of the present invention provide methods and systems for protecting probes by using an intelligent current sensing switch. For example, embodiments of the invention can be used to limit or stop the current flowing through probe tips on a probe card, used in automated test equipment to test semiconductor chips or integrated circuits (ICs), if it exceeds a certain set point. However, embodiments of the present invention can be applied to other type of testing systems and be used to test other types of devices under test (DUTs) as well.

As discussed previously, conventional methods of preempting probe damage from excessive current are not only time-consuming, but they are also ineffective in certain tester configurations. The probe protector circuit described herein addresses those deficiencies by using an intelligent current limiter/current sensing switch applied to each power probe to prevent current through the probe from exceeding the probe's specified trip point value. The circuit first attempts to current limit at a certain level, wherein the current level for limiting is programmable. When the current has been so limited for a duration of time, the circuit triggers a switch which then opens up the connection between DPS and the DUT being tested to prevent any further current from flowing.

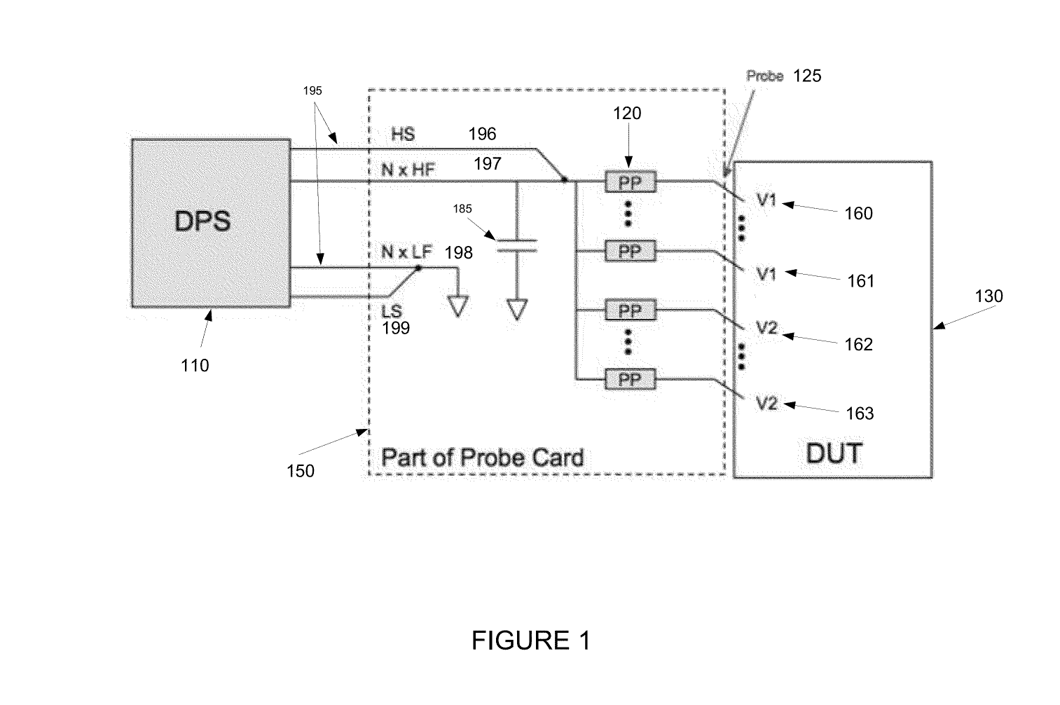

Referring initially to FIG. 1, a test apparatus is shown illustrating the interconnections between the probe protector circuit, the DPS and the DUT in accordance with an embodiment of the present invention. As illustrated in FIG. 1, a dedicated probe protector circuit for each probe can be connected in series between the DPS 110 and the DUT 130. In a different embodiment, the probe protector circuit can also be connected in series to at least two probes in parallel. In this embodiment, each probe protector circuit monitors multiple probes at a time. While this embodiment does not provide individual probe protection for each probe, it occupies a smaller footprint than embodiments comprising a separate probe protector circuit for each probe.

In one embodiment, the probe protector circuit 120 is a small circuit module, for example, occupying less than 0.2 square inches, that can be mounted directly on the probe card 150. For example, probe 125 in FIG. 1, located on probe card 150, has a probe protector circuit 120 connected in series between the probe tip and the DPS 110. In another embodiment, the probe protector circuit can be mounted wherever it is convenient as long as it is still connected in series with the probe it is protecting. In a different embodiment, the protector circuit can be integrated directly into the probe card itself instead of being first mounted on a separate module. In yet another embodiment, the probe protector circuit can be configured into a custom IC or programmed into a programmable analog IC.

In one embodiment, the probe tip makes contact with the DUT at bonding pad 160, which is connected to one of the DUT power rails. Bonding pads 160 through 161 shown in FIG. 1 are tied together. Similarly bonding pads 162 through 163, also connected to the power rails of the DUT, are connected together.

In one embodiment, the DPS 110 delivers power through power lines 195 to the DUT. Power lines 195 constitute a Kelvin connection comprising four sets of lines (high force lines 197, low force lines 198, high sense line 196 and low sense line 199) for forcing highly accurate differential DC voltages. Bypass capacitor 185 is a filter capacitor used to dampen the noise. In one embodiment the probe protector operates over a DPS voltage range of 0V to 8V. In other embodiments, the DPS voltage range can be higher or lower.

The force lines 197 and 198 carry the current from the DPS to the DUT. The sense lines 196 and 199 connect in close proximity to the DUT and ensure that the voltage at the DUT is close to the DPS voltage. The Kelvin connection forms a feedback loop that allows the DC source to force an accurate differential voltage through the resistive wires between the source and the DUT. Without the Kelvin connection, the small resistance in the force lines 197 and 198 would cause a voltage drop across the line between the DPS and the DUT. The sense lines 198 and 199 of the Kelvin connection carry no current, therefore, they are immune to errors caused by voltage drops.

In one embodiment, the probe protector circuit 120 is connected to the circuit after the sense lines 198 and 199. Therefore, it is important that the resistance of the probe protector circuit 120 is very low so as to avoid a high voltage drop on the line before the circuit connects with DUT 130. In one embodiment the switch on resistance of the probe protector circuit is less than 25 milliohms typically around 35 milliohms maximum. However, in another embodiment the switch on resistance can be reduced even further by trading off with other factors such as a slight increase in the module area for the circuit.

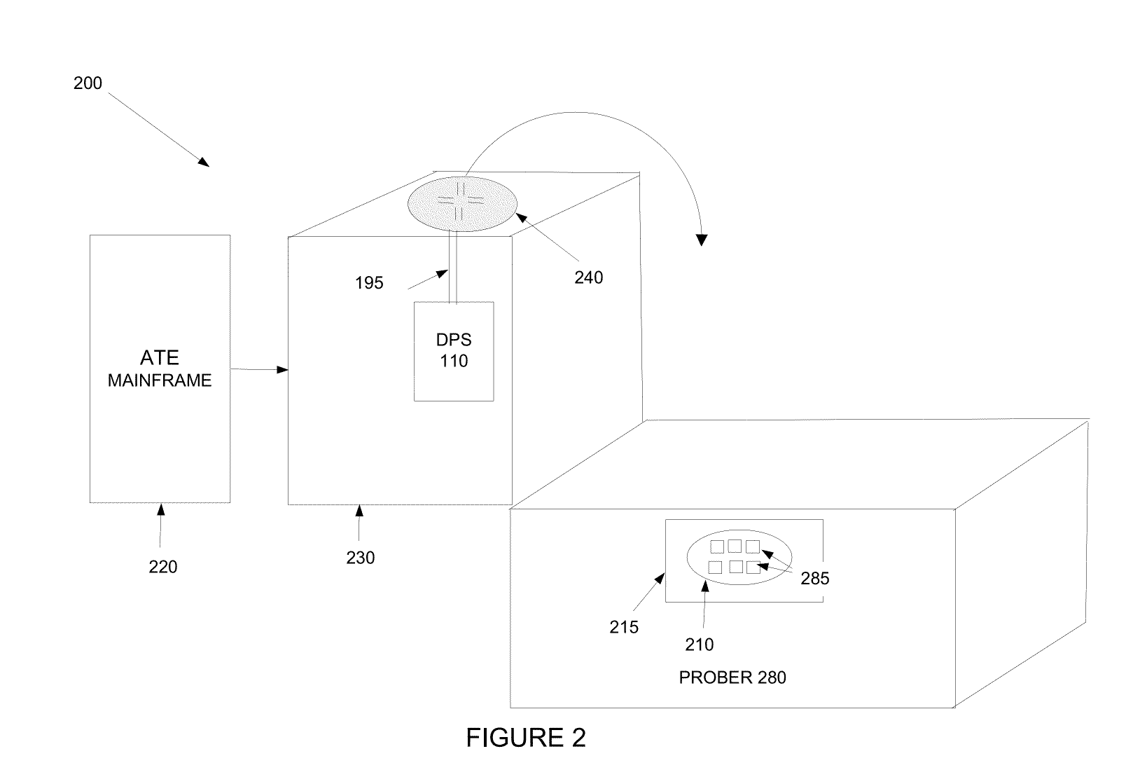

Referring now to FIG. 2, an exemplary system 200 to test semiconductor chips in accordance with an embodiment of the present invention is shown. The automated test equipment (ATE) mainframe 220 runs the test programs that control the testing of the DUTs. It can also comprise a user interface for the user of the ATE to load the test programs and run tests for the DUTs connected to the ATE 220. The ATE 220 is connected to a test head 230. In one embodiment, however, the ATE mainframe 220 can simply be a power supply, for example a 48 Volt power supply, and most of the intelligence for running the test is built into test head 230.

Test head 230 can comprise a DPS board 110 which is connected to probe card 240 through power lines 195. In one embodiment, there may be multiple DPS boards within test head 230 depending on how much current will be drawn by the DUTs. The principles of this invention are particularly advantageous in current heavy applications where each DUT draws a large amount of current from the DPS modules. In such current heavy applications, the probe tips are all the more susceptible to being burned out because of the high amounts of currents being drawn by the DUTs.

Probe card 240 can be located on test head 230 and comprises the probe protector circuitry. The probe card also comprises probe tips that make electrical contact with the bonding pads on the DUT and deliver power to the DUTs. The probe tips can typically be fine wire, spring loaded or have a different form factor. The circuits on the DUT are electrically stimulated through the power supplied to the DUTs via these probe tips.

The test head 230 is typically folded down onto the wafer prober 280 so that the probe tips on the probe card 240 can come into electrical and mechanical contact with the DUTs 285. The DUTs 285 are typically dies on a wafer that have not been singulated yet. Each wafer typically comprises several die that are probed at the same time. In certain applications, such as memory devices, for example, several hundred die may be probed at the same time. The array of probes is aligned in a way such that they correspond with the array of bonding pads for the dies. Typically, each die on wafer 210 is positioned and aligned under the array of probes, and platen 215 carrying wafer 210 is moved up to allow contact of the probes with the chip. Mechanical controls allow for x,y,z and Θ positioning of the platen so that the probe points can be brought into contact with the chip being tested at the precise locations of the bonding pads. The positions of the die not passing the test are transmitted through the test head back to the ATE mainframe to alert the user or store in memory for later use.

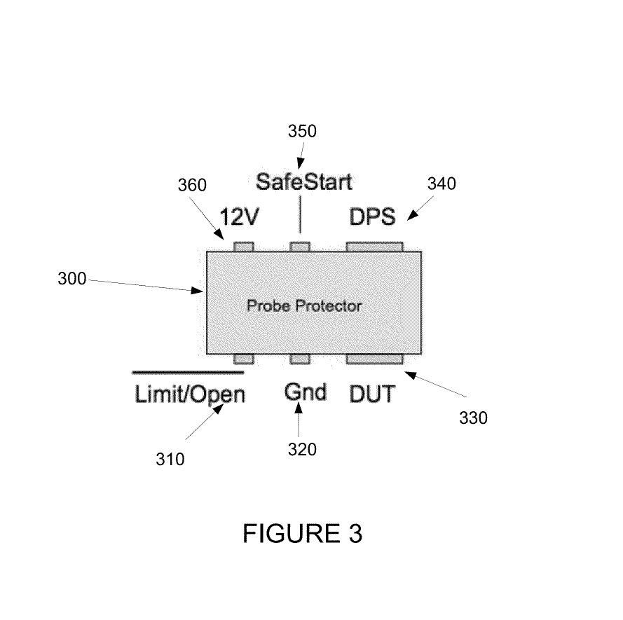

Referring now to FIG. 3, an exemplary pin diagram for a typical probe protector circuit according to an embodiment of the present invention is shown. Pin 360 is connected to 12 V DC. In one embodiment, the probe protector circuit module requires approximately 12 Volts+/−5% utility power to operate, but in other embodiments the module may operate at a higher or lower voltage. In one embodiment, the 12V DC to operate the protector circuit module may come from an auxiliary supply voltage, or in a different embodiment the protector circuit may run off the DPS voltage. Pin 350 is connected to the SafeStart signal that allows the probe protector switch to start in the open position so that the connection between the DPS and the DUT is initially open when the probe tip comes into contact with the bonding pad of the DUT and DPS is turned on. Pin 340 is connected to the DPS. Pin 320 is connected to ground. Pin 330 is connected to the DUT. Pin 310 is an open drain output L̅i̅m̅i̅t̅/̅O̅p̅e̅n̅, which pulls low to indicate a current limit or open condition.

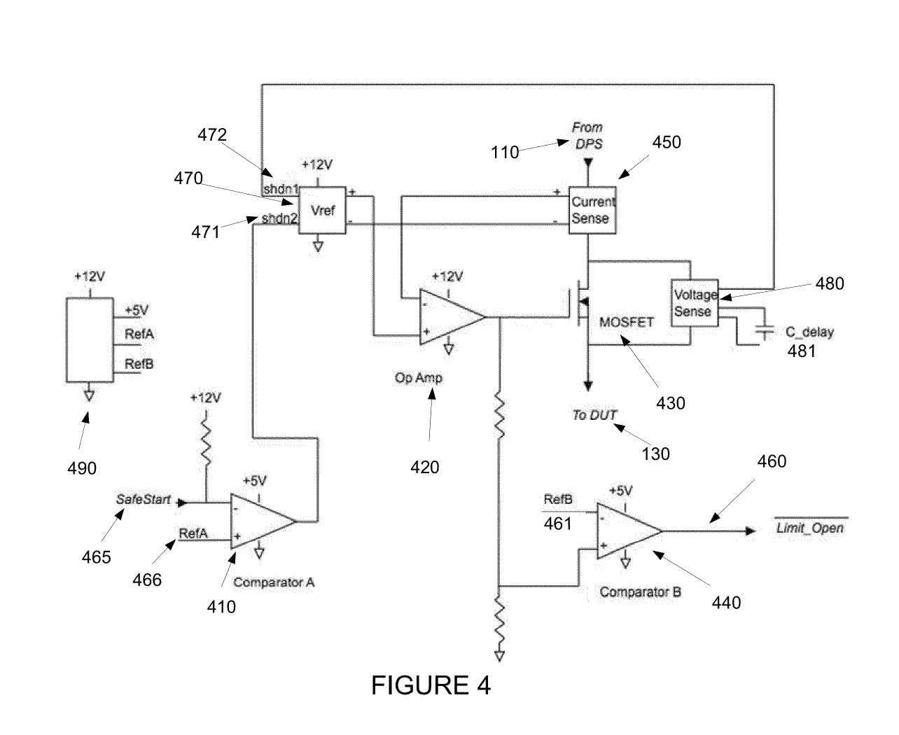

FIG. 4 is an exemplary schematic of the probe protector circuit 120 according to an embodiment of the present invention. The probe protector circuit comprises a MOSFET 430 which connects DPS to the DUT when it is turned on and disconnects the power source from the DUT when it is off. Accordingly, MOSFET 430 acts like a switch. In another embodiment, a different type of switching element other than a MOSFET can also be used. Current sense module 450 senses the current flowing between DPS 110 and DUT 130 and Op Amp 420 determines whether it has exceeded a certain trip point. In one embodiment, the trip point of the current sense module in the probe protector circuit is set to 1.2 A+/−10%. In other embodiments, this trip point can be adjusted according to the needs of the tester system. The trip point can be set at the factory to any value between several hundred milliamps and several Amps. In other embodiments the trip point may be set by an analog or digital control signal. In one embodiment, the probe protector circuit passes positive current up to the trip point value. The protector circuit passes negative current for capacitive discharge. The negative current is not limited in the same way as the positive current.

Voltage sense module 480 senses the voltage drop across the MOSFET 430 and sends a signal to open the MOSFET switch if the voltage crosses a predetermined threshold. In one embodiment, voltage sense module 480 can be a thermal sensing circuit that can also be used to open the MOSFET switch 430. In other embodiments the trip point from the current sense module can be utilized to open the MOSFET.

Operational amplifier 420 controls the gate voltage of MOSFET 430. Operational amplifier 420, together with Current Sense module 450 and MOSFET 430, form a current source whose source value is set to the current trip point. Under normal DUT operation, the current drawn by the DUT is less than this trip point, and the Operational Amplifier 420 output goes to almost 12V, which drives the MOSFET 430 into strong conduction, making the MOSFET 430 act as a switch in the “on” state. Voltage reference module 470 provides a fixed (constant) voltage between the Current Sense module 450 negative terminal and the non-inverting input terminal of operational amplifier 420 irrespective of the loading on the device, power supply variations, temperature changes, and the passage of time.

Voltage reference module 470 has two inputs, shdn1 signal 472 and shdn2 signal 471, which shut down the voltage reference module 470 thereby causing the output of operational amplifier 420 to be driven low. The output of the voltage sense module 480 is connected to the shdn1 signal 472. The output of comparator A 410 is connected to shdn2 signal 471.

In normal operation with no shorted connections at the DUT, the output of the current sense module 450 is less than the reference voltage from the voltage reference module 470. The non-inverting input of the amplifier 420 is therefore at a higher voltage than the inverting input resulting in the gate of MOSFET 430 being driven at a high positive voltage, close to 12 V. The MOSFET 430 therefore acts as a closed switch for current to flow from the DPS to the DUT.

Comparator B 440, compares a fraction of the output voltage of amplifier 420, which is the same as the gate voltage to MOSFET 430, to a reference value on line RefB 461. The reference value is generated by voltage regulator 490, which produces reference voltages for both comparators 410 and 440. The 12V supply voltage on the regulator 490, in one embodiment, can come from an auxiliary supply voltage. If the output of amplifier 420 goes below the reference value, the comparator output L̅i̅m̅i̅t̅/̅O̅p̅e̅n̅ line 460 pulls low to indicate that MOSFET switch 430 is in a current limiting state or an open state.

The non-inverting terminal of Comparator A 410 is tied to a reference voltage RefA 466 generated by voltage regulator 490. The inverting input of Comparator A 410 is tied to SafeStart line 465 which can either be tied high to 12 Volts through a pull-up resistor or optionally can be connected to the DPS voltage. In one embodiment the SafeStart control signal allows control of the switch initial condition. The SafeStart control signal allows the user to start the MOSFET switch in an initial condition that is not going to draw much current.

If SafeStart line 465 is tied high, then the output of Comparator A 410 will be low and the shutdown signal 471, shdn2, to voltage reference 470 will not be triggered. If SafeStart line 465 is connected to the DPS voltage, then shdn2 signal 471 will be triggered if the SafeStart signal is pulled low because of the DPS voltage going to 0V. The reference voltage connected to the non-inverting terminal of operational amplifier 420 will turn off and the output of amplifier 420 will be driven low, which in turn will turn the MOSFET 430 off. When the MOSFET switch is turned off, DPS is disconnected from the DUT.

It is readily understood by persons skilled in the art that in some embodiments of the invention, Comparator A 410 and Comparator B 440 may be comprised of operational amplifiers acting as comparators.

FIG. 5 depicts a flowchart 500 of an exemplary process of protecting probes by using an intelligent current sensing switch when a defective DUT is encountered in accordance with an embodiment. The present invention, however, is not limited to the description provided by flowchart 500. Rather, it will be apparent to persons skilled in the relevant art(s) from the teachings provided herein that other functional flows are within the scope and spirit of the present invention.

Flowchart 500 will be described with continued reference to exemplary embodiments described above in reference to the prior figures, though the method is not limited to those embodiments.

Referring now to FIG. 5, at block 502, a probe protector circuit 120 is placed in series between a DPS module 110 and a probe 125, wherein the probe 125 is connected to a defective DUT and is used to supply power to the DUT.

At block 504, the probe 125 is connected to a bonding pad on the defective DUT. Under typical operation, the SafeStart signal 465 will be tied high so the switch will start off in the closed position.

Current sense module 450, at block 506, senses that the current is approaching the trip point specified for the probe tip, which in this embodiment is set at 1.2 A. At block 508, when the DUT current approaches the trip point, for example, if the current begins to go over 1 A on a probe that has a trip point set at 1.2 A, amplifier 420 beings to operate in its linear region. The operational amplifier 420, the current sense block 450 and the MOSFET 430 form a current source which limits the current to the trip point value. In one embodiment, the current sense trip point can be factory set based on resistors chosen for the current sense module 450 circuit. In this embodiment, the trip point of the current sense module is not programmable so as to reduce the circuitry size and keep the probe protector module footprint as small as possible.

In another embodiment, the circuit could be redesigned to make the trip point of the current sense module 450 programmable. For example, control lines could be added to the circuit so that it can be configured to be reprogrammed according to the type of probe tip it is designed to protect. If the maximum current that the probe tip can handle, for example, is 1.2 A, then the programmed threshold value for the current sense module trip point should not exceed 1.2 A. In one embodiment, the circuit is integrated into a dedicated chip in order to keep the footprint small despite the addition of control lines to make the current sense module programmable.

Under normal operation the voltage drop across MOSFET 430 is very low because of the low resistance of the MOSFET. When the MOSFET 430 operates as a current source, however, the voltage drop across the MOSFET increases, increasing the power dissipation in the MOSFET. At block 508, the voltage drop is sensed by the voltage sense module 480, which asserts shdn1 signal 472 to shut down voltage reference module 470 after a time determined by capacitor C_delay 481. When voltage reference module 470 shuts down, a bias circuit ensures that the amplifier 420 will drive the MOSFET gate to the ground, causing the MOSFET to act like an open switch. As a result, MOSFET switch 430 opens up disconnecting DPS 110 from the damaged DUT. The larger the voltage that the voltage sense module 480 senses across the MOSFET 430, the quicker the shutdown occurs.

In this way, the probe protector circuit advantageously acts as an intelligent current limiter. It limits the current for a while until certain conditions apply after which it switches to turn off the current in order to protect the probe and particularly the probe tip that would otherwise potentially melt or damage. Unlike prior art techniques, the intelligent current switch protects the probe automatically without user intervention, thereby, saving customers unnecessary time and expense in replacing damaged probes.

With the MOSFET 430 open, the full DPS 110 voltage appears across the MOSFET, but with zero current. This holds the voltage reference module 470 in shutdown and latches the MOSFET in the open state. When the MOSFET switch in the circuit is tripped open because of an excessive current condition, it can be reset either by setting the DPS to 0V, disconnecting the DPS, or by disconnecting the probe from the bonding pad on the DUT. In another embodiment, the circuit does not latch when an excessive current condition is encountered, but instead is designed so that the switch goes back to the closed state when the current level drops below the trip point threshold.

At step 512, an open drain output L̅i̅m̅i̅t̅/̅O̅p̅e̅n̅ pulls low to indicate a current limit or open condition. In one embodiment, the L̅i̅m̅i̅t̅/̅O̅p̅e̅n̅ outputs of several probe protector circuits in the tester apparatus can be logically AND-ed together and read from a digital pin. This signal can be used as part of the normal fail processing in the tester to determine if a shorted DUT was encountered during the testing process. Because of the intelligence built into the design of the probe protector circuit, it advantageously switches off the current automatically if it exceeds a certain threshold. By comparison, in prior art methods, the user would have to ramp up the voltage and current limits slowly while taking intermediate measurements to make sure that no DUTs were shorted.

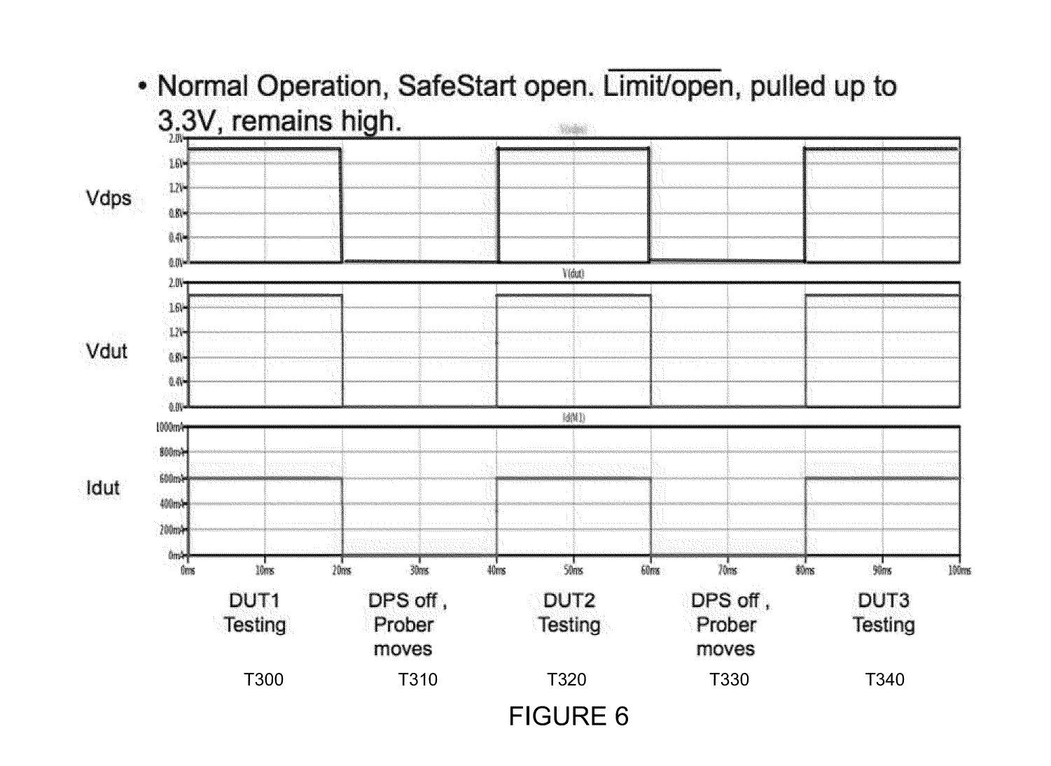

FIG. 6 is a waveform diagram illustrating normal operation of the testing apparatus in accordance with one embodiment of the present invention. FIG. 6 illustrates the behavior of the input DPS voltage (Vdps), the DUT voltage (Vdut) and the current flowing through the DUT (Idut) where three test normal DUTs are tested by apparatus 200 and where the trip point for the probe protector circuit is set at 1.2 A. The SafeStart signal is open and not connected to the DPS in this case. As shown in FIG. 6, Vdps and Vdut are both around 1.8V during the cycles when the probe is connected to the DUTs (DUT1, DUT2 and DUT3) during timeframes T300, T320 and T340. The current flowing through from the DPS to the DUT, indicated by Idps, is around 600 mA, which is below the trip point of the protector circuit. Therefore, the waveforms in this diagram indicates normal operation where no damaged DUTs were encountered. Accordingly, the L̅i̅m̅i̅t̅/̅O̅p̅e̅n̅ signal is pulled high during the entire time period.

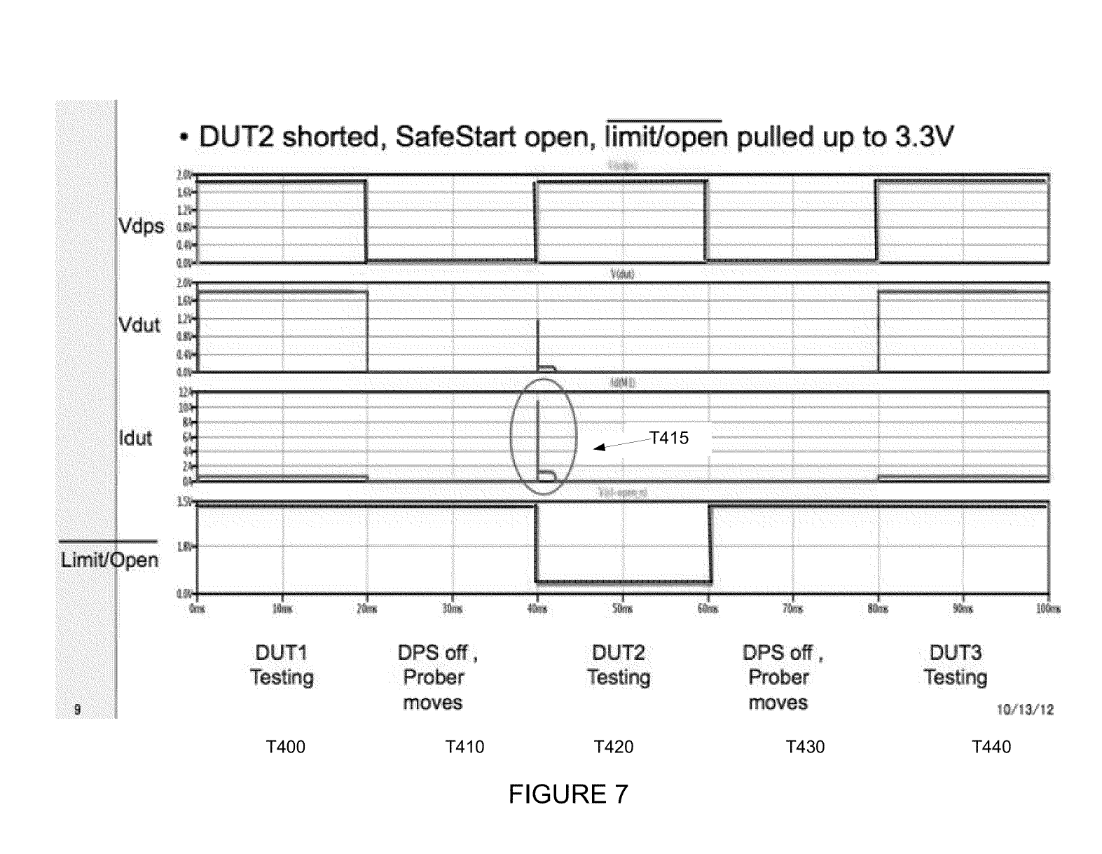

FIG. 7 is a waveform diagram illustrating how a short on one of the DUTs is handled by the probe protector circuit in accordance with one embodiment of the present invention. FIG. 7 illustrates the behavior of the DPS voltage (Vdps), the DUT voltage (Vdut), the current flowing through the DUT (Idut), and the L̅i̅m̅i̅t̅/̅O̅p̅e̅n̅ signal where two normal and one shorted DUT are tested by apparatus 200 and where the trip point for the probe protector circuit is set at 1.2 A. In FIG. 7, DUT2 is shorted and, accordingly, Vdut and Idut display abnormal behavior during time period T420. Because the SafeStart signal is open, MOSFET switch 430 is closed when the probe is moved to DUT2 during window T420. This results in an initial spike in current before the probe protection mechanism is invoked. Idut spikes to approximately 11 A and Vdut spikes to approximately 1.2V. The L̅i̅m̅i̅t̅/̅O̅p̅e̅n̅ signal is driven low during the T420 time window to indicate that a short at DUT2 has been encountered.

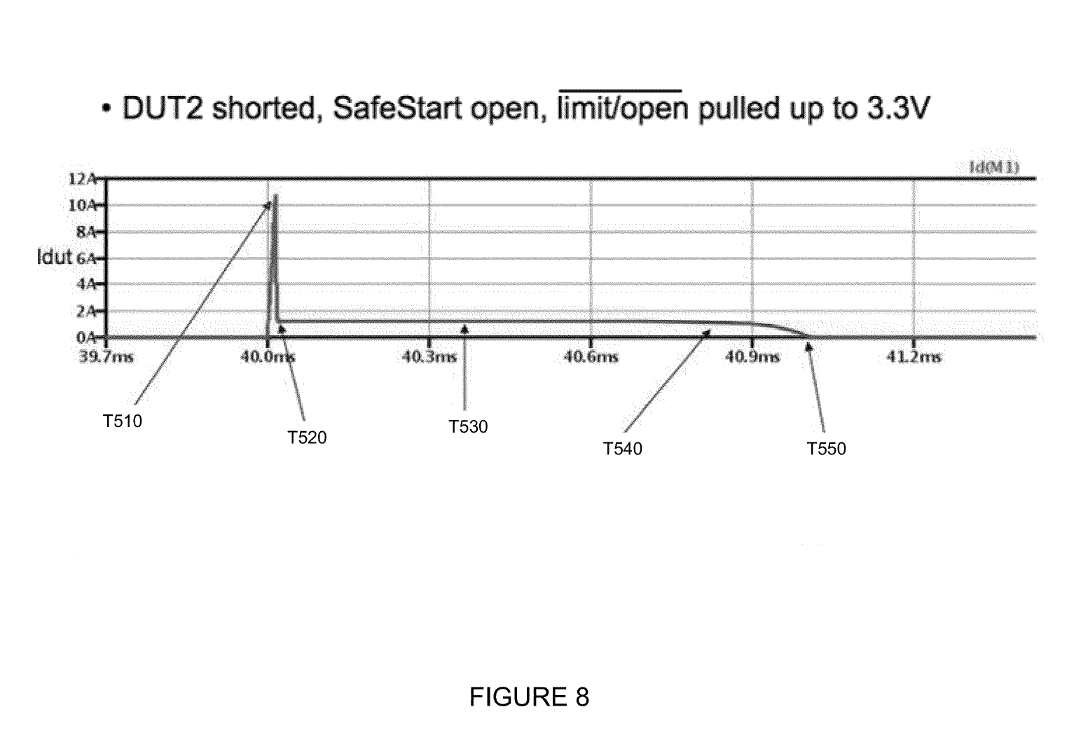

FIG. 8 is a magnified view of event T415 from FIG. 7 illustrating the behavior of current Idut when a shorted DUT is encountered in accordance with one embodiment of the present invention. Event T415 takes place during time window T420 as seen in FIG. 7 when shorted DUT2 is encountered. Referring now to FIG. 8, at T510, initially, the MOSFET switch is on because SafeStart signal 465 is open. The inrush of current into the shorted DUT is limited during this phase by only the external circuit impedance, which results in a high current spike. Because of the slew rate of operational amplifier 420, the MOSFET switch does not go from a closed state to an open state instantaneously. Consequently, as the voltage at the MOSFET 430 gate drops from about 12V to around 2 to 4 volts (the voltage at which the circuit operates in current limiting mode) there will be a short influx of high current resulting in the spike at T415.

At T520, after about 20 microseconds, the probe protector circuit begins to current limit at 1.2 A. The larger the inrush current, the faster the probe protector circuit will limit it. If the short circuit is removed while the current is being limited, for example at T530, the Vdut will recover to the Vdps value. The probe protector circuit stays in current limit mode in this waveform diagram till about T540. The time it stays in the current limit mode depends on the DPS voltage and the DUT short circuit resistance. Higher DPS voltage and lower short circuit resistance reduce this time. Finally at T550, the probe protector MOSFET switch opens. It takes about 10 ms to reset after this time.

Due to the finite gain bandwidth of the operational amplifier 420, it takes a certain time to transition from the closed switch state to the current limiting state when the DUT connection is shorted. As stated above, during this time, current through the switch is limited primarily by the external circuit impedance. Because the transition time duration is short, even though the current is high, the probe tip temperature rise is still small.

However, in one embodiment, the closed switch to current limiting transition time can be eliminated by starting with the switch in the open state, and having it close as the DPS voltage ramps up. By connecting SafeStart line 465 to the DPS voltage, Comparator A 410 accomplishes this by shutting down voltage reference module 470 while SafeStart is below the voltage value on line RefA 466. The RefA voltage value must be below the voltage sense block 480 threshold voltage so that the switch is not latched in the open position.

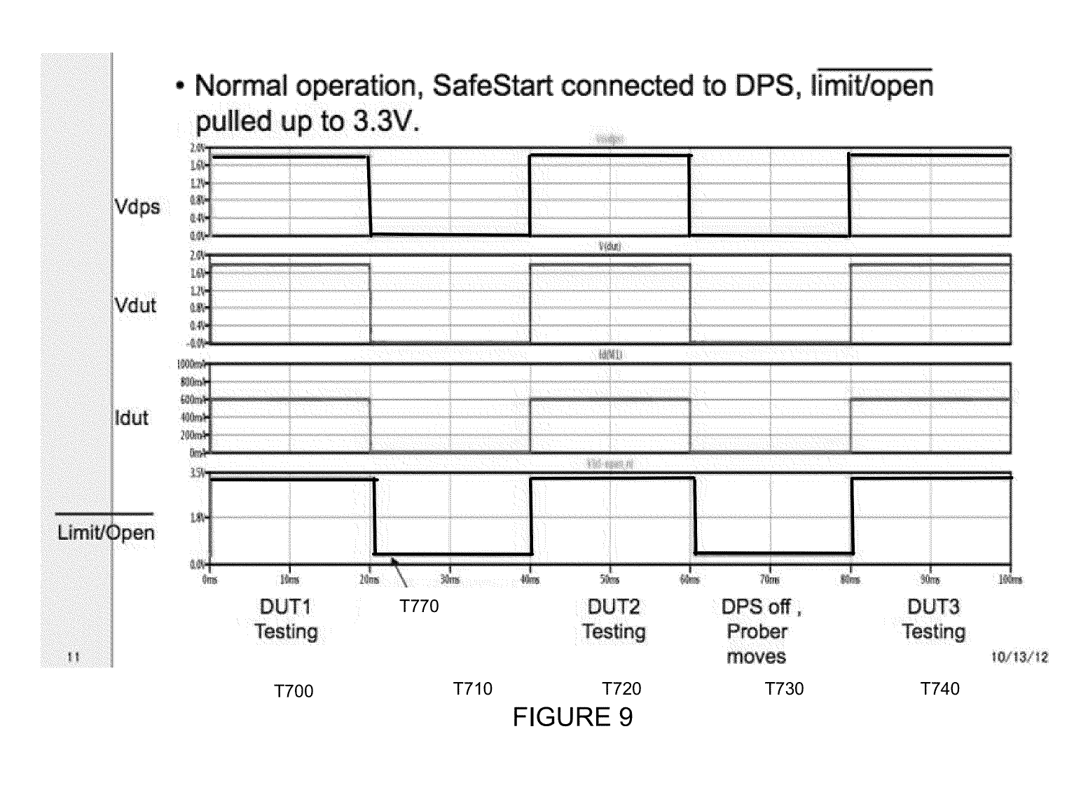

In one embodiment, SafeStart can also be controlled by an external logic signal with the appropriate timing. If the DPS voltage is not set below a minimum threshold voltage, for example 0.25V, before the probes are contacted with the DUT, then it is possible to use an external control signal from one of the tester utility bits to drive the SafeStart signal indicated in FIG. 4. If that control signal drives SafeStart low while the probe contact is made, then the switch will be open during probe contact and no current will flow. When the external control signal drives SafeStart high, the switch will be closed. If the external signal follows DPS, the probe protector will operate as shown in FIGS. 9-12 where SafeStart is connected to the DPS. The inrush current will be limited to 1.2 A and the probes will be protected.

FIG. 9 is a waveform diagram illustrating normal operation of the testing apparatus with the SafeStart signal connected to the DPS in accordance with one embodiment of the present invention. FIG. 9 illustrates the behavior of the DPS voltage (Vdps), the DUT voltage (Vdut), the current flowing through the DUT (Idut), and the L̅i̅m̅i̅t̅/̅O̅p̅e̅n̅ signal where three normal DUTs are tested by apparatus 200 and where the trip point for the probe protector circuit is set at 1.2 A When SafeStart is connected to the DPS signal, it is pulled low whenever DPS (the control signal) voltage goes low. Therefore, during time windows T710 and T730 when Vdps is low, the MOSFET switch is held open, and accordingly, the L̅i̅m̅i̅t̅/̅O̅p̅e̅n̅ signal is driven low during those timeframes. In this case, because SafeStart is causing the switch to be held open, the low on the L̅i̅m̅i̅t̅/̅O̅p̅e̅n̅ signal does not indicate an abnormal condition. The waveforms are similar to FIG. 6 in all other respects and indicate that the DUTs do not contain any problems. As shown in FIG. 9, Vdps and Vdut are both around 1.8V during the cycles when the probe has made contact with the DUTs (DUT1, DUT2 and DUT3) and the switch has moved to a closed state.

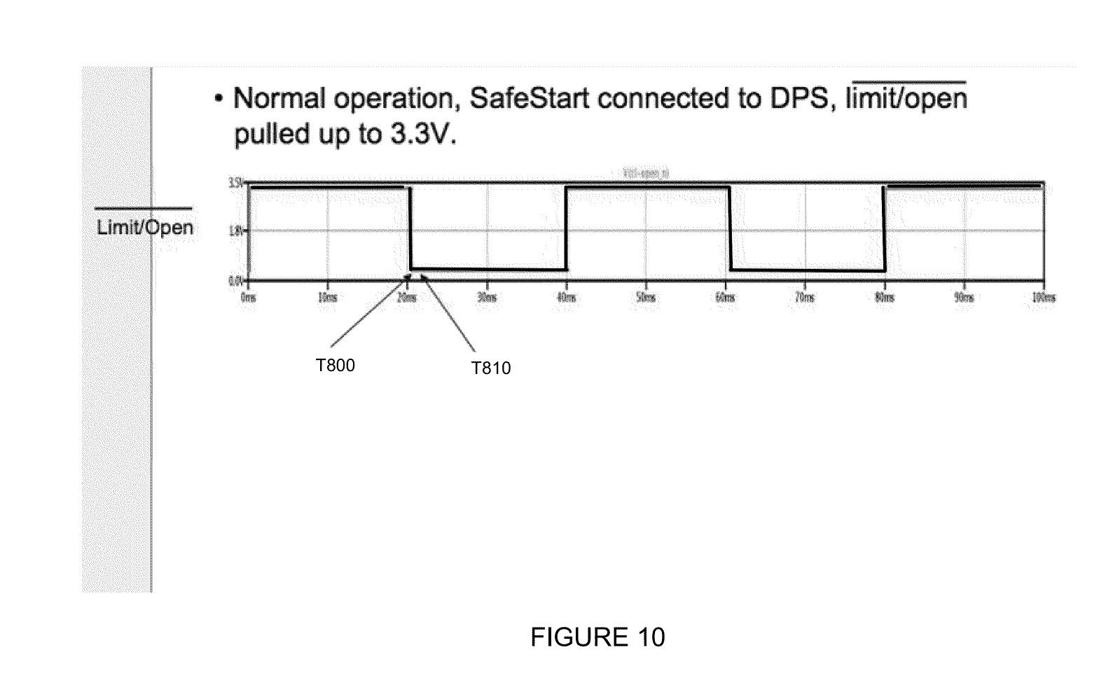

FIG. 10 is a magnified view of event T770 from FIG. 9 illustrating the behavior of signal L̅i̅m̅i̅t̅/̅O̅p̅e̅n̅ when the SafeStart signal is connected to the DPS in accordance with one embodiment of the present invention. At T800 when SafeStart is below 0.25V, the probe protector MOSFET switch 430 is held in the open position and signal L̅i̅m̅i̅t̅/̅O̅p̅e̅n̅ responds accordingly. The SafeStart signal must remain below 0.25V for 3 ms, as indicated by event T810, for the probe protector switch to fully open.

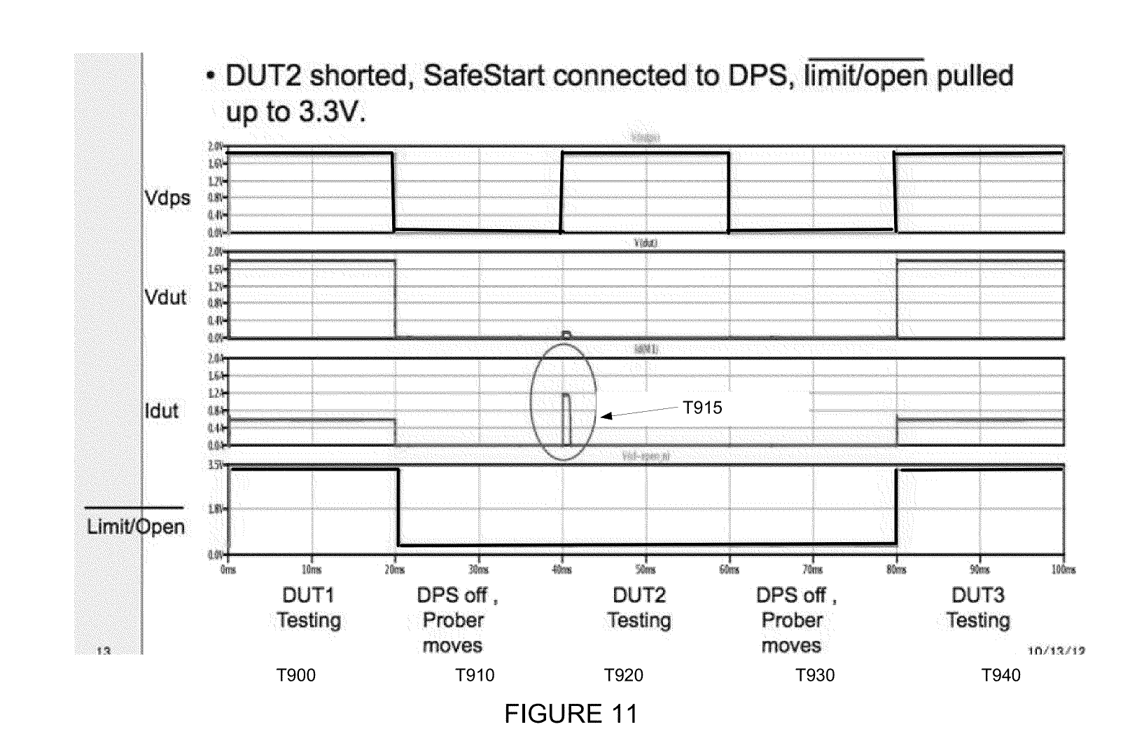

FIG. 11 is a waveform diagram illustrating how a short on one of the DUTs is handled by the probe protector circuit when the SafeStart signal is connected to the DPS in accordance with one embodiment of the present invention. FIG. 11 illustrates the behavior of the DPS voltage (Vdps), the DUT voltage (Vdut), the current flowing through the DUT (Idut), and the L̅i̅m̅i̅t̅/̅O̅p̅e̅n̅ signal where two normal and one shorted DUT (DUT2) are tested by apparatus 200 and where the trip point for the probe protector circuit is set at 1.2 A. In FIG. 11, DUT2 is shorted and, accordingly, Vdut and Idut display abnormal behavior during time period T920. However, as is apparent from event T915 when compared to event T415 from FIG. 7, there is no initial current spike in Idut, nor a corresponding voltage spike at Vdut in this case. In fact, the Idut current never goes above 1.2 A.

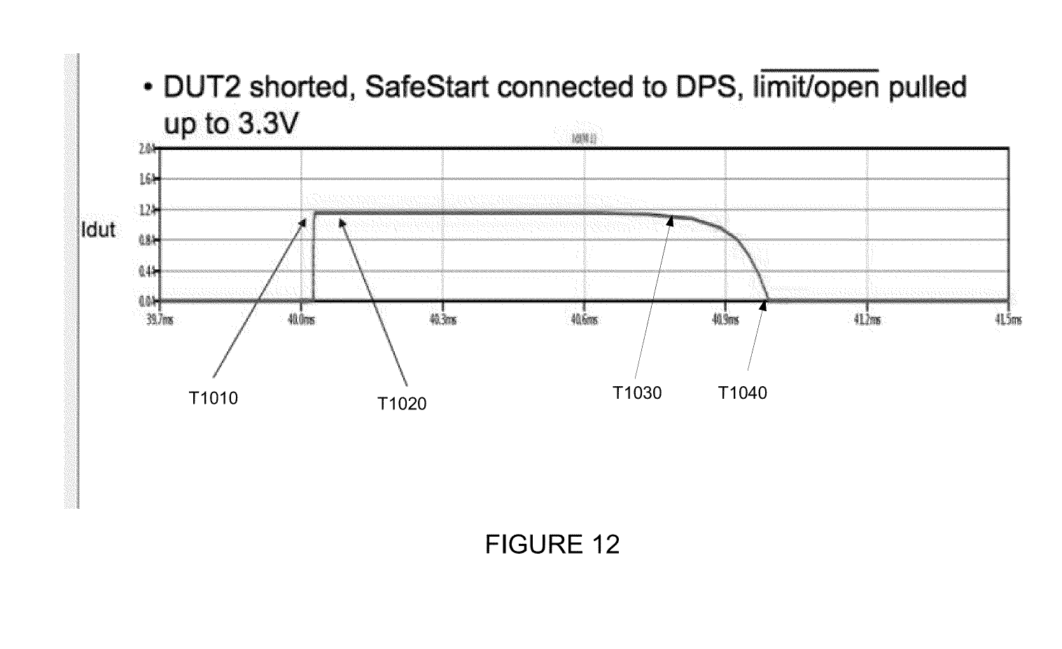

FIG. 12 is a magnified view of timeframe T915 from FIG. 10 illustrating the behavior of current Idut when a shorted DUT is encountered with the SafeStart signal connected to the DPS in accordance with one embodiment of the present invention. At event T1010, because the probe protector switch is initially open, there is no inrush of current into the shorted DUT. At event T1020, after the switch has closed, the probe protector current limits at 1.2 A. The probe protector circuit stays in current limit mode in this waveform diagram till about T1030. The time it stays in the current limit mode depends on the DPS voltage and the DUT short circuit resistance. Higher DPS voltage and lower short circuit resistance reduce this time. Finally at T1040, the probe protector MOSFET switch opens again.

While the foregoing disclosure sets forth various embodiments using specific block diagrams, flowcharts, and examples, each block diagram component, flowchart step, operation, and/or component described and/or illustrated herein may be implemented, individually and/or collectively, using a wide range of hardware, software, or firmware (or any combination thereof) configurations. In addition, any disclosure of components contained within other components should be considered as examples because many other architectures can be implemented to achieve the same functionality.

The process parameters and sequence of steps described and/or illustrated herein are given by way of example only. For example, while the steps illustrated and/or described herein may be shown or discussed in a particular order, these steps do not necessarily need to be performed in the order illustrated or discussed. The various example methods described and/or illustrated herein may also omit one or more of the steps described or illustrated herein or include additional steps in addition to those disclosed.

While various embodiments have been described and/or illustrated herein in the context of fully functional computing systems, one or more of these example embodiments may be distributed as a program product in a variety of forms, regardless of the particular type of computer-readable media used to actually carry out the distribution. The embodiments disclosed herein may also be implemented using software modules that perform certain tasks. These software modules may include script, batch, or other executable files that may be stored on a computer-readable storage medium or in a computing system.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best utilize the invention and various embodiments with various modifications as may be suited to the particular use contemplated.

Embodiments according to the invention are thus described. While the present disclosure has been described in particular embodiments, it should be appreciated that the invention should not be construed as limited by such embodiments, but rather construed according to the below claims.

What is claimed is:

1. A method of protecting probes used in automated testing, said method comprising:
supplying power to a device under test (DUT) from a device power source (DPS) through a probe, wherein the probe is coupled to a contact point on the DUT;
monitoring a current flow through the probe via a probe protector circuit that is coupled in series between the DPS and the DUT to determine if the current flow is below a predetermined threshold current; and
limiting the current flow if the current flow exceeds the predetermined threshold current.

2. The method of claim 1 further comprising transmitting a signal operable to disconnect the DPS from the DUT after a period of time has elapsed during which the current flow exceeds the predetermined threshold current.

3. The method of claim 2 further comprising providing an output signal operable to indicate that the current flow has exceeded the predetermined threshold current.

4. The method of claim 2 further comprising resetting the probe protector circuit to reconnect the DPS to the DUT, wherein resetting is selected from the group comprising: setting the DPS voltage to 0V, disconnecting the DPS, disconnecting the probe from the contact point on the DUT, and receiving an externally generated reset signal.

5. The method of claim 2 further comprising disconnecting the DPS from the DUT by turning off a switch inside the probe protector circuit connecting the DPS to the DUT.

6. The method of claim 5 wherein said switch is a transistor.

7. The method of claim 6 wherein the transmitting is in response to detecting a voltage drop across the transistor that exceeds a predetermined threshold voltage.

8. The method of claim 6 further comprising operating the probe protector circuit in safety mode, wherein the safety mode comprises keeping the transistor in an off state while DPS is on and before coupling the probe to the contact point on the DUT to avoid any transient spikes in current.

9. The method of claim 7 wherein the period of time that elapses before the transmitting of the signal to disconnect the DPS from the DUT is dependent on a magnitude of the voltage drop detected across the transistor.

10. The method of claim 1 wherein the predetermined threshold current is programmable.

11. An apparatus for protecting probes used in automated testing, said apparatus comprising:
a probe operable to provide power to a device under test (DUT) from a device power source (DPS), wherein the probe is coupled to a contact point on the DUT; and
a probe protector circuit connected to the probe in series between the DPS and the DUT, wherein the probe protector circuit comprises:
a current sense module operable to monitor a current flow from the DPS to the DUT to determine if the current flow is below a predetermined threshold current level; and
a switch for controlling the connection from the DPS to the DUT, wherein the switch is coupled to the current sense module and further wherein the switch is operable to be used in conjunction with the current sense module to limit the current flow if it exceeds the predetermined threshold current level.

12. The apparatus of claim 11 wherein the probe protector circuit further comprises a voltage sense module operable to sense a voltage across the switch and further operable to transmit a signal that causes the switch to open and disconnect the DPS from the DUT if the voltage across the switch exceeds a predetermined threshold level voltage.

13. The apparatus of claim 11 wherein the probe protector circuit further comprises a thermal sensing module operable to sense a temperature of the switch and further operable to transmit a signal that causes the switch to open and disconnect the DPS from the DUT if the temperature of the switch exceeds a predetermined threshold.

14. The apparatus of claim 12 wherein the voltage sense module is operable to transmit the signal to disconnect the DPS from the DUT after the switch has limited the current flow for a predetermined period of time during which the current flow exceeds the predetermined threshold current.

15. The apparatus of claim 14 wherein the predetermined period of time depends on the magnitude of the voltage sensed across the switch by the voltage sense module.

16. The apparatus of claim 11 wherein the predetermined threshold current level is programmable.

17. The apparatus of claim 11 wherein the probe protector circuit is operable to be reset by a procedure selected from the group comprising: setting the DPS voltage to 0V, disconnecting the DPS, disconnecting the probe from the contact point on the DUT, and receiving an externally generated reset signal.

18. The apparatus of claim 11 wherein the probe protector circuit is operable to generate an output signal to indicate that the current flow has exceeded the predetermined threshold current level.

19. The apparatus of claim 11 wherein the probe protector circuit further comprises a signal operable to maintain the switch in an off state when coupling the probe to the contact point on the DUT while DPS is on to avoid any transient spikes in current.

20. A tester system comprising:
a test head comprising at least one device power source (DPS) and a probe card comprising a plurality of power probes, wherein the plurality of power probes are connected to and derive power from the DPS; and
a prober for positioning at least one wafer, wherein the at least one wafer comprises a plurality of devices under test (DUTs) to be tested,
wherein the test head is operable to be lowered onto the prober to allow each of the plurality of power probes to connect and provide power to an associated DUT on the wafer and wherein each respective probe of the plurality of power probes comprises:
a probe protector circuit connected to the respective probe in series between the DPS and the associated DUT, wherein the probe protector circuit comprises:
a current sense module operable to monitor a current flow from the DPS to the associated DUT to determine if the current flow is below a predetermined threshold current level; and
a switch for controlling the connection from the DPS to the associated DUT, wherein the switch is coupled to the current sense module and further wherein the switch is operable to be used in conjunction with the current sense module to limit the current flow if it exceeds the predetermined threshold current level.

21. The system of claim 20 wherein the probe protector circuit further comprises a voltage sense module operable to sense a voltage across the switch and further operable to transmit a signal that causes the switch to open and disconnect the DPS from the DUT if the voltage across the switch exceeds a predetermined threshold level voltage.

22. The system of claim 20 wherein the predetermined threshold current level is programmable.

23. The system of claim 20 wherein the probe protector circuit is operable to be reset by a procedure selected from the group comprising: setting the DPS voltage to 0V, disconnecting the DPS, disconnecting the probe from the contact point on the DUT, and receiving an externally generated reset signal.

24. The apparatus of claim 20 wherein the probe protector circuit is operable to generate an output signal to indicate that the current flow has exceeded the predetermined threshold current level.

25. The apparatus of claim 20 wherein the probe protector circuit is operable to generate a signal operable to maintain the switch in an off state when coupling the probe to the contact point on the DUT while DPS is on to avoid any transient spikes in current.
